(19) United States
(12) Patent Application Publication
(10) Pub. No.: US 2007/0052080 A1
(43) Pub. Date: Mar. 8, 2007

(54) THREE-DIMENSIONAL INTERCONNECT INTERPOSER ADAPTED FOR USE IN SYSTEM IN PACKAGE AND METHOD OF MAKING THE SAME

(76) Inventor: Chih-Hsien Chen, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/164,176

(22) Filed: Nov. 14, 2005

(30) Foreign Application Priority Data
Sep. 2, 2005 (TW) 094130063

(51) Int. Cl. H01L 21/44

(52) U.S. Cl. 257/686; 438/598

(57) ABSTRACT

A three-dimensional interconnect interposer adapted for use in system in package (SIP) includes a wafer, at least an embedded passive device and at least an interconnect pattern disposed on the front surface of the wafer, a plurality of cavities exposing the inner contact pads of the interconnect pattern formed on the back surface of the wafer, and a back connect pattern disposed on the back surface of the wafer electrically connected to the interconnect pattern and the embedded passive device through the inner contact pads.

### BACKGROUND OF THE INVENTION

1. Field of the Invention

The present invention relates to an interconnect interposer adapted for use in system in package (SIP) and method of making the same, and more particularly, to a method that uses a wafer as a three-dimensional interconnect interposer. The wafer has an embedded passive device electrically connected to a chip bonded to the front surface of the wafer. The chip is electrically connected to a printed circuit board bonded to the back surface of the wafer via an interconnect pattern disposed on the front surface of the wafer. Thus, the size of SIP is dramatically reduced.

2. Description of the Prior Art

SIP is one of the most important techniques in electronic production miniaturization. The concept of SIP is to integrate chips of different functions into a package structure. In comparison with individually-packaged structures, electronic product may have high efficiency, small size and multi-functions.

With reference to FIG. 1, FIG. 1 is a schematic diagram of a conventional SIP structure. As shown in FIG. 1, the conventional SIP structure includes a package substrate 12, a plurality of chips 14 of different functions bonded to the surface of the package substrate 12, and an encapsulation layer (not shown). The package substrate 12 has a plurality of contact pads 16, and the chips 14 also include a plurality of contact pads 18 electrically connected to the contact pads 16 of the package substrate 12 via conducting wires 20. In addition, the conventional SIP structure 10 further includes at least a passive device 22 bonded to the contact pads 16 of the package substrate 12 so as to connect to the chips 14 and constitute a complete circuit.

However, the passive device 22 of the conventional SIP structure 10 is bonded to the package substrate 12 by surface mount technology, and coupled to the chips 14 via the contact pads 16, 18, and the conducting wires 20. Thus, signal would decay. In addition, the passive device 22 also increases the overall size of the conventional SIP structure 10.

### SUMMARY OF THE INVENTION

It is therefore an object of the claimed invention to provide an interconnect interposer adapted for use in system in package (SIP) and method of making the same.

According to the claimed invention, a method of forming a three-dimensional interconnect interposer adapted for use in system in package (SIP) is provided. A wafer having a front surface and a back surface is provided. Then, at least an embedded passive device and at least an interconnect pattern electrically connected together are formed on the front surface of the wafer, the interconnect pattern including a plurality of inner contact pads. Subsequently, a plurality of cavities are formed on the back surface of the wafer, the cavities exposing the inner contact pads. Thereafter, a back connect pattern is formed on the back surface of the wafer, the back connect pattern being electrically connected to the interconnect pattern and the embedded passive device via the inner contact pads.

According to the claimed invention, a three-dimensional interconnect interposer adapted for use in system in package (SIP) is provided. The three-dimensional interconnect interposer includes a wafer having a front surface and a back surface; at least an embedded passive device and an interconnect pattern disposed on the front surface of the wafer, the embedded passive device and the interconnect pattern being electrically connected together, the interconnect pattern including a plurality of inner contact pads; a plurality of cavities disposed on the back surface of the wafer, the cavities exposing the inner contact pads; and a back connect pattern disposed on the back surface of the wafer, the back connect pattern being electrically connected to the interconnect pattern and the embedded passive device via the inner contact pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional SIP structure.

FIG. 2 to FIG. 16 are schematic diagrams illustrating a method of forming a three-dimensional interconnect interposer adapted for use in SIP in accordance with a preferred embodiment of the present invention.

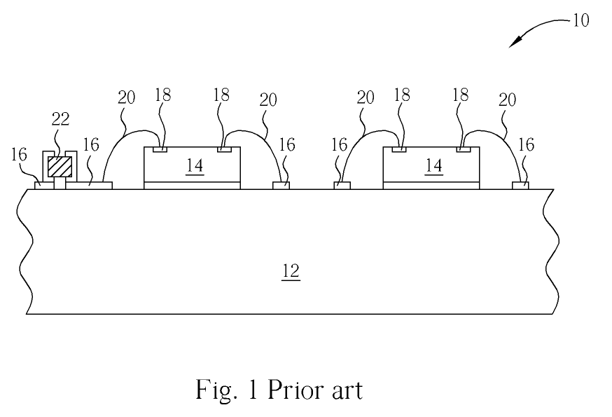

### DETAILED DESCRIPTION

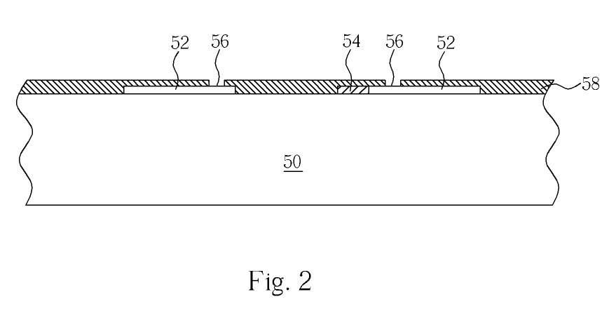

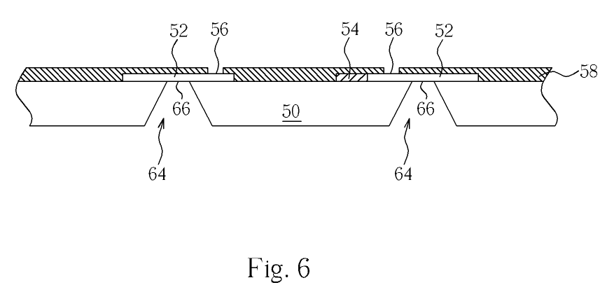

With reference to FIG. 2 to FIG. 16, FIG. 2 to FIG. 16 are schematic diagrams illustrating a method of forming a three-dimensional interconnect interposer adapted for use in SIP in accordance with a preferred embodiment of the present invention. It is appreciated that the method of the present invention is a wafer-level process, and only one single three-dimensional interconnect interposer is illustrated for the sake of highlighting features of the present invention. As shown in FIG. 2, a wafer 50 e.g. a silicon wafer is provided, and at least an interconnect pattern 52 and at least an embedded passive device 54 are formed on the front surface of the wafer 50 by e.g. deposition, lithography and etching techniques. The interconnect pattern 52 and the embedded passive device 54 are electrically connected together, and the interconnect pattern 52 further includes a plurality of front contact pads 56. The arrangement and resistance of the interconnect pattern 52, and the quantities of the front contact pads 56 are decided basing on the standard of chips to be bonded. The embedded passive device 54 may be a resistor, a capacitor, a inductor, etc, and its position, quantity and standard is based on circuit design. Subsequently, an insulating layer 58 e.g. a silicon dioxide layer or a silicon nitride layer is formed the front surface of the wafer 50, and the insulating layer 58 is then partially etched to expose the front contact pads 56.

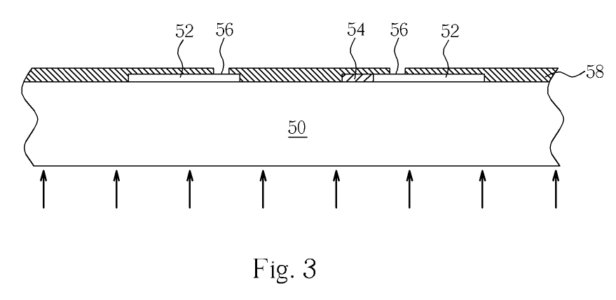

As shown in FIG. 3, a wafer thinning process is performed if necessary from the back surface of the wafer 50 to reduce the thickness to e.g. 20 to 500 micrometers. The wafer thinning process can be implemented by for example grinding, polishing, CMP, wet etching or plasma etching, or any combinations of the above processes.

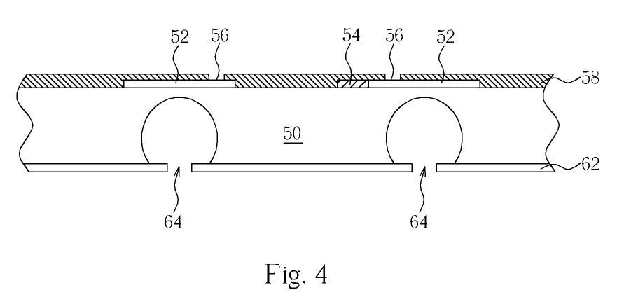

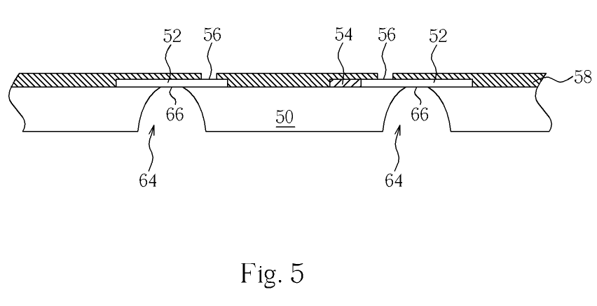

As shown in FIG. 4 and FIG. 5, a mask pattern 62 is formed on the back surface of the wafer 50, and the wafer 50 is etched to form a plurality of cavities 64 which expose the inner contact pads 66 of the interconnect pattern 52. It is to be appreciated that the method of forming the cavities 64 may differ if the thickness of the wafer 50 or the shape of the cavities 64 is different. In this embodiment, an isotropic wet etching process is carried out to form the cavities 64 where each cavity 64 has a rounded sidewall. In such a case, successive steps of forming back connect pattern are facilitated. If the wafer 50 is thicker or the cavities 64 are arranged densely, the fabrication of the cavities 64 cannot be implemented by simply performing an isotropic wet etching process. In such a case, the mask pattern 62 must be removed, and an anisotropic dry etching process e.g. a plasma etching process is performed to expose the inner contact pads 66 of the interconnect pattern 52 via the cavities 64 as shown in FIG. 5.

The method of forming the cavities 64 is not limited to the above steps, and may be carried out by performing an anisotropic wet etching process, such as using potassium hydroxide (KOH) solution, ethylenediamine-pyrocatechol-water (EDP) or tetramethyl ammonium hydroxide (TMAH), so that each cavity 64 has an inclined sidewall.

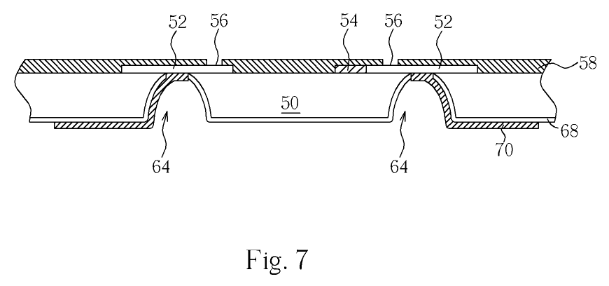

The following steps follow FIG. 4 and FIG. 5. As shown in FIG. 7, an insulating layer 68 e.g. a silicon dioxide layer or a silicon nitride layer is formed on the back surface of the wafer 50, and the insulating layer 68 is partially etched to expose the inner contact pads 66. The insulating layer 68 is able to prevent current leakage or short circuit problems. Subsequently, a back connect pattern 70 electrically connected to the inner contact pads 66 is formed on the insulating layer 68.

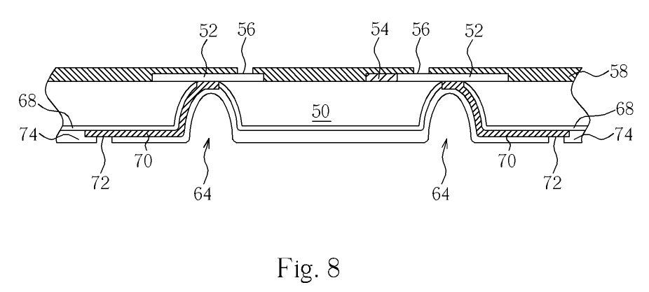

As shown in FIG. 8, a passivation layer 74 such as silicon dioxide layer, a silicon nitride layer or a silicon oxynitride layer is formed on the back connect pattern 70, is formed on the back connect pattern 70, and the passivation layer 74 is partially etched to expose back contact pads 72 of the back connect pattern 70.

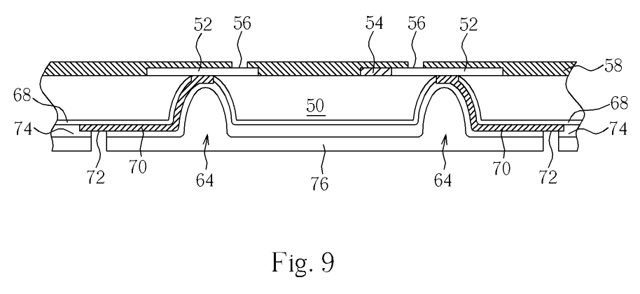

If the wafer 50 is thinner, another passivation 76 made of polymer e.g. benzocyclobutene (BCB) or polyimide, can be formed on the passivation layer 74 and filled into the cavities 64 to enhance protection effect as shown in FIG. 9. The passivation layer 76 is then patterned to expose the back contact pads 72. Except for the above steps, the passivation layers 74 and 76 may be formed respectively, and patterned simultaneously to expose the back contact pads 72.

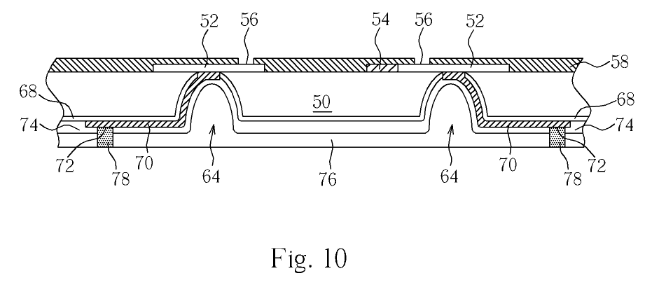

As shown in FIG. 10, a plurality of solder balls (or solder bumps) 78 are formed on the back contact pads 72 to weld the wafer to a printed circuit board (not shown). The above steps illustrate the back side process of forming the three-dimensional interconnect interposer. The front side process is illustrated hereinafter.

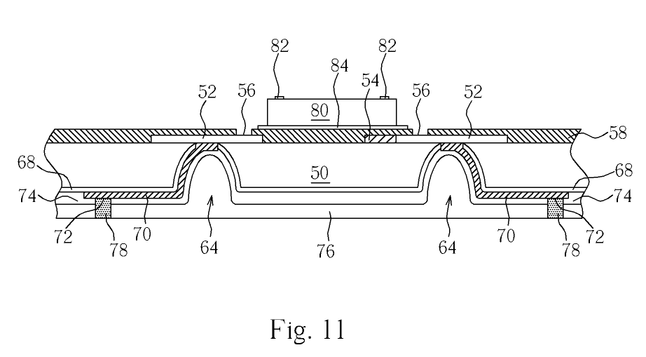

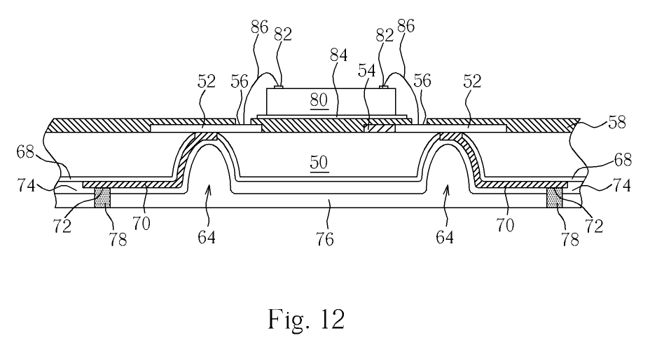

As shown in FIG. 11, at least a chip 80 having a plurality of contact pads 82 is provided. The chip 80 is bonded to the surface of the insulating layer 58 with a bonding layer 84. As shown in FIG. 12, conducting wires 86 are used to electrically connected to the contact pads 82 of the chip 80 and the inner contact pads 66 of the interconnect pattern 52. In such a manner, the chip 80 is electrically connected to the interconnect pattern 52 and the embedded passive device 54, and further connected to the printed circuit board (not shown). It is noted that the chip 80 and the interconnect pattern 52 may also be connected by flip chip bonding.

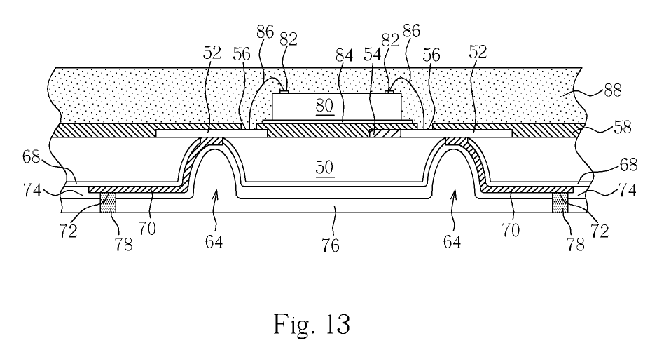

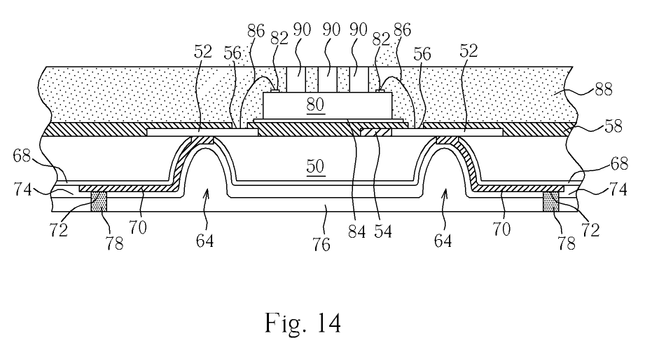

As shown in FIG. 13, a front passivation layer 88 is formed on the insulating layer 58 and the chip 80. The material of the front passivation layer 88 may be polymer such as benzocyclobutene (BCB) or polyimide. In addition, if some parts of the chip 80 e.g. optical devices or MEMS devices cannot be shielded, the front passivation layer 88 can be formed locally such as by halftone printing. The rest area can be protected by transparent protection caps 90 e.g. glass protection caps as shown in FIG. 14.

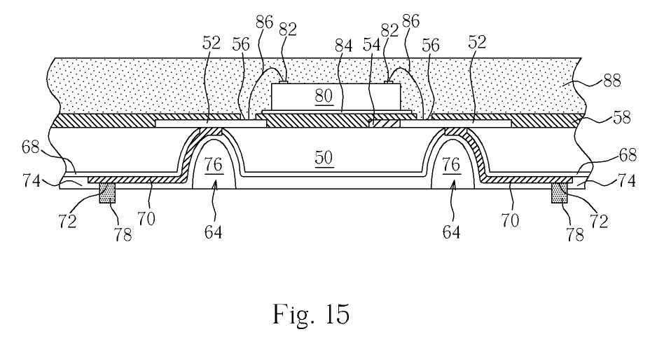

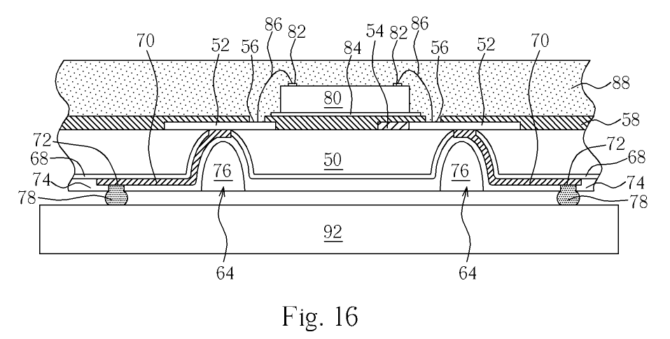

As shown in FIG. 15, excessive passivation layer 76 located outside the cavities 64 is removed, and a segment process is performed to form a plurality of SIP structure. As shown in FIG. 16, the back surface of the wafer 50 is placed on a printed circuit board 92, and a reflow process is performed to weld the wafer 50 to the printed circuit board 92 with the solder balls 78.

In conclusion, the three-dimensional interconnect interposer and method of making the same have the following advantages:

(1) using the wafer to form the three-dimensional interconnect interposer and forming the embedded passivation device in the wafer can reduce signal decadence and SIP size;

(2) wafer-level package can improve fabrication efficiency; and

(3) fabrication of the embedded passive device and the wafer-level package are implemented separately on different sides of the wafer, and chips are well protected so that rework is easy to perform.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a three-dimensional interconnect interposer adapted for use in system in package (SIP), comprising:
providing a wafer comprising a front surface and a back surface;
forming at least an embedded passive device and at least an interconnect pattern electrically connected together on the front surface of the wafer, the interconnect pattern comprising a plurality of inner contact pads;
forming a plurality of cavities on the back surface of the wafer, the cavities exposing the inner contact pads; and
forming a back connect pattern on the back surface of the wafer, the back connect pattern being electrically connected to the interconnect pattern and the embedded passive device via the inner contact pads.

2. The method of claim 1, further comprising performing a wafer thinning process to thin the wafer from the back surface of the wafer prior to forming the cavities.

3. The method of claim 2, wherein the wafer thinning process comprises optionally performing a grinding process, a polishing process, a CMP process, a wet etching process or a plasma etching process, or any combinations of the above processes.

4. The method of claim 1, wherein the cavities are formed by forming a mask pattern on the back surface of the wafer and performing an isotropic wet etching process, and each cavity has a rounded sidewall.

5. The method of claim 4, further comprising removing the mask pattern and performing an anisotropic dry etching process to expose the inner contact pad through the cavities subsequent to performing the isotropic wet etching process.

6. The method of claim 1, wherein the cavities are formed by forming a mask pattern on the back surface of the wafer and performing an anisotropic wet etching process or a plasma etching process, and each cavity has an inclined sidewall.

7. The method of claim 1, further comprising depositing at least a back passivation layer on the back connect pattern subsequent to forming the back connect pattern.

8. The method of claim 7, wherein a material of the back passivation layer comprises silicon dioxide, silicon nitride, silicon oxynitride or polymer.

9. The method of claim 7, wherein the back connect pattern further comprises a plurality of back contact pads, and the method further comprises forming a plurality of openings in the back passivation layer corresponding to the back contact pads to expose the back contact pads.

10. The method of claim 9, further comprising welding the back contact pads to a printed circuit board, wherein the interconnect pattern and the embedded passive device are electrically connected to the printed circuit board via the back contact pads.

11. The method of claim 1, wherein the interconnect pattern further comprises a plurality of front contact pads, and the method further comprises forming an insulating layer on the embedded passive device and the interconnect pattern, the insulating layer having a plurality of openings exposing the front contact pads.

12. The method of claim 11, further comprising bonding a chip on the insulating layer, the chip being electrically connected to the interconnect pattern and the embedded passive device via the front contact pads.

13. The method of claim 12, further comprising forming a front passivation layer on the insulating layer.

14. The method of claim 13, wherein a material of the front passivation layer is polymer.

15. The method of claim 13, wherein the front passivation layer further comprises a transparent cap disposed over the chip.

16. A three-dimensional interconnect interposer adapted for use in system in package (SIP), comprising:
a wafer having a front surface and a back surface;
at least an embedded passive device and an interconnect pattern disposed on the front surface of the wafer, the embedded passive device and the interconnect pattern being electrically connected together, the interconnect pattern comprising a plurality of inner contact pads;
a plurality of cavities disposed on the back surface of the wafer, the cavities exposing the inner contact pads; and
a back connect pattern disposed on the back surface of the wafer, the back connect pattern being electrically connected to the interconnect pattern and the embedded passive device via the inner contact pads.

17. The three-dimensional interconnect interposer of claim 16, wherein the back connect pattern comprises a plurality of back contact pads to weld the back surface of the wafer to a printed circuit board, and the interconnect pattern and the embedded passive device are electrically connected to the printed circuit board via the back contact pads.

18. The three-dimensional interconnect interposer of claim 16, wherein the embedded passive device and the interconnect pattern further comprise a plurality of front contact pads, and the front contact pads are electrically connected to at least a chip bonded to the front surface of the wafer.
